(19) United States
(12) Patent Application Publication
(10) Pub. No.: US 2023/0324636 A1
(43) Pub. Date: Oct. 12, 2023

(54) System-Level Power Distribution, Optical Signal Distribution, and Thermal Cooling for High Bandwidth Communication

(71) Applicant: Fathom Radiant, PBC, Boulder, CO (US)

(72) Inventors: Dipankar Behera, Broomfield, CO (US); J. Israel Ramirez, Denver, CO (US); Ryan Boesch, Louisville, CO (US)

(21) Appl. No.: 18/298,260

(22) Filed: Apr. 10, 2023

Related U.S. Application Data
(60) Provisional application No. 63/330,164, filed on Apr. 12, 2022.
(60) Provisional application No. 63/336,562, filed on Apr. 29, 2022.

(51) Int. Cl. G02B 6/42; H01L 23/50

(52) U.S. Cl. CPC G02B 6/4268; H01L 23/50

(57) ABSTRACT

System architecture for devices with integrated electrical and optical power and signal distribution coupled with thermal dissipation. Systems include an electrical signal and electrical power delivery subsystem, an optical engine, an electrical interposer between the electrical signal and electrical power delivery subsystem and the optical engine, and an optical element to exchange optical signals with the optical engine and to exchange optical signals and optical power with an optical interface. Electrical signals and electrical power delivery from the electrical interposer to the optical engine and optical signal delivery from the optical element to the optical engine are provided through a common plane on the optical engine.

This application claims the benefit of pat. app. Nos. 63/330,164, entitled “Electrical and Optical Power and Signal Delivery to Opto-Electronic Integrated Circuits,” filed 12 Apr. 2022; and 63/336,562, entitled “System-Level Power and Signal Distribution and Thermal Cooling” filed 29 Apr. 2022; and incorporates them herein by reference.

### FIELD OF THE INVENTION

The present invention relates to a system-level architecture of power distribution and optical signal distribution for high-bandwidth integrated circuits integrated with thermal cooling solutions.

### DISCUSSION OF RELATED ART

A silicon photonics package utilizes silicon-based materials to construct optical components, such as waveguides, modulators, detectors, and filters, which are integrated on a single chip. The package consists of a substrate on which the photonic integrated circuit (PIC) is mounted and connected to input/output (I/O) pads. The I/O pads serve the purpose of providing power to the PIC and electrical signaling of data. The substrate may be made of various materials, such as silicon, glass, or ceramic, based on the application's needs. For multi-wavelength links, an external laser source or a laser device transferred to a cavity in the silicon generates the wavelengths. The light from these lasers is coupled into waveguides on the chip, modulated, and transferred into a shared output waveguide, which is then coupled to external optical fiber or other optical components. This tightly integrated multiplexing operation is not always power-efficient due to losses at each stage in the optical path.

### SUMMARY OF INVENTION

A system provides an electrical signal and electrical power delivery subsystem, an optical engine, an electrical interposer between the electrical signal and electrical power delivery subsystem and the optical engine, and an optical element configured to exchange optical signals with the optical engine and to exchange optical signals and optical power with an optical interface. Electrical signals and electrical power from the electrical interposer to the optical engine and optical signal delivery from the optical element to the optical engine are provided through a common plane on the optical engine. Optical signal from the optical interface to the optical element may enter perpendicular to the common plane or parallel to it.

In some systems, the optical element adjoins the electrical interposer. A cooling system may be provided on the other side of the optical engine from the electrical interposer, for example in direct contact with a bare semiconductor die on the optical engine. The cooling system may use air cooling, liquid cooling or multiple methods.

The electrical interposer may include a cutout so optical signals can be delivered to the optical engine through the cutout. The optical element can be a detachable component. Optical signals and electrical signals and electrical power are delivered to the optical engine via a common substrate. The optical element is packaged in the common substrate.

The optical engine may adjoin the electrical interposer and deliver optical signals through the cutout. This allows that system to be very thin, for example the thickness of the optical engine, the electrical interposer, and the optical element all combined is under 5 mm.

An energy-efficient, high-bandwidth communication system is enabled by coupling optical fiber to opto-electronics which are integrated with a silicon digital logic process. This system describes methods to minimize misalignment between the optical fiber and the management of electrical power and signal delivery, cooling, while keeping mechanical tolerance loops small.

Transfer-printed multi-wavelength optical devices are disposed on the surface of an electrical integrated circuit (EIC) with a compact multiplexor stacked for wavelength combination. This allows for higher bandwidth density.

### BRIEF DESCRIPTION OF THE DRAWINGS

FIG. 1 is a block diagram showing system level architecture.

FIG. 2A is an isometric view of an example device.

FIG. 2B is a detailed cross sectional view of the example of FIG. 2A, showing the hidden components in the apparatus.

FIG. 3A is an isometric view of the electrical signal and power delivery subsystem from the example of FIG. 2A, showing the optical engine, package substrate, optical element and optical fiber.

FIG. 3B shows a detailed cross sectional view of the device of FIG. 3A.

FIG. 4 is an isometric drawing showing a second embodiment.

FIG. 5 is an isometric drawing showing a third embodiment.

FIGS. 6A and 6B are isometric drawings showing a fourth embodiment. FIG. 6A shows this embodiment with a detached cable while FIG. 6B shows the cable attached.

FIG. 7A is an isometric drawing showing a fifth embodiment. FIG. 7B is a cutaway view of the embodiment of FIG. 7A.

### DETAILED DESCRIPTION OF THE INVENTION

Table 1 lists elements of the present invention and their corresponding reference

TABLE 1

| | |
|---|---|
| 10 | System level apparatus |
| 20, 20A, | Packaged electrical and optical subsystems |
| 20B, 20C, | |
| 20D | |
| 100 | Electrical signal and power delivery subsystem |
| 110 | Electrical interposer |
| 120 | Optical element |
| 130 | Optical engine |
| 140 | Optical fiber |
| 150 | Cooling subsystem |
| 150A | Air assisted cooling subsystem |
| 150B | Liquid assisted cooling subsystem |
| 160 | Thermal power/heat dissipation from the apparatus |
| 162 | Thermal power/heat conduction to cooling subsystem |
| 164 | Bidirectional electrical power and signal delivery |
| 166 | Bidirectional optical power and signal delivery between |
| | optical element and optical engine |
| 168 | Bidirectional optical power and signal delivery between |
| | optical fiber and optical element |
| 170 | Multiple wavelengths generated in the optical engine |
| 232 | Secondary integrated circuit |
| 242 | Optical fiber array holder |
| 251 | Finned heat sink |
| 252 | Evaporative vapor chamber for heat spreading in |
| | cooling subsystem |
| 312 | Cutout in printed circuit board 100 and electrical |
| | interposer 110 |
| 410 | Active electrical interposer with active and passive |
| | electrical elements |
| 410A | Active electrical interposer with embedded optical |
| | element 120 |
| 500 | Liquid cooling subsystem |
| 510 | Cold liquid inlet |
| 520 | Warm liquid outlet |
| 610 | Detachment of optical sub-system 600 to optical |
| | engine 130 |
| 620 | Reattachment of optical sub-system 600 to optical |
| | engine 130 |
| 710 | Common substrate interposer |

Table 1 shows elements in the following drawings with their reference numbers.

High-Performance computing power density requirements have increased with the computation speed and power over the years. Computing chips with high power density (>50 W/cm²) have had to employ complex heat dissipation solutions like composite materials with high thermal conductivity, extra-long fins for air-cooled solutions, cold blocks and/or immersion of electronics in a liquid material. Additionally, metal cover lids and thermal interface material between the chip and the cooling solution increases the overall thermal resistance of the system. The figures discussed below relate to a high-performance communication system where optical elements (i.e. optical lenses, fiber optics etc.) are coupled to opto-electronic devices, integrated circuits and/or packages to enable high-bandwidth through the system (>1 Tb/sec per optical channel). Key components have been disaggregated to breakdown mechanical tolerance loops, increase mechanical tolerance, increase system serviceability and/or a combination of any of the above. The key advantages of this system include but not limited to: 1) Physical separation of system-driving electronic components from Optical components to minimize thermal disturbance on the optical components; 2) System-level management of stack-up coefficient of thermal expansion (CTE) by modularizing the compute electronics into its standalone package; and 3) Mechanical tolerance loops are reduced to a minimum for looser system alignment.

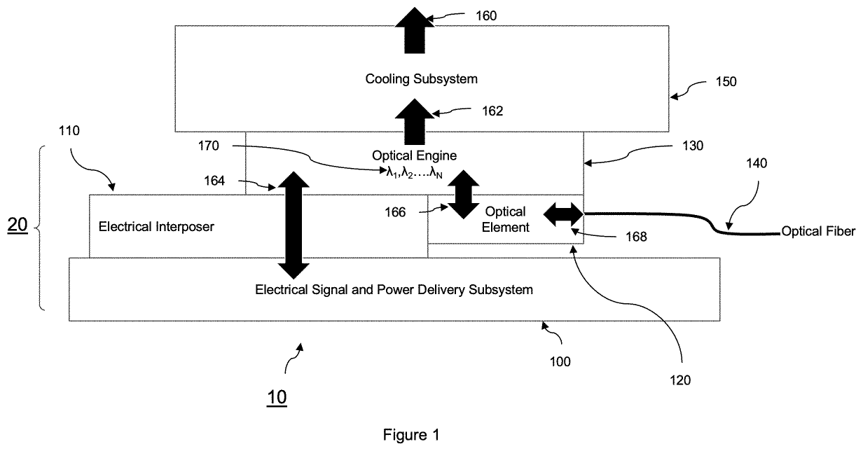

FIG. 1 shows a high-level depiction of the system architecture for device 10 with integrated electrical and optical power and signal distribution coupled with thermal dissipation. Device 10 includes an electrical signal and power delivery subsystem 100, an electrical interposer 110, an optical element 120, an optical engine 130 and cooling subsystem 150. Optical element 120 generally connects to an optical fiber 140.

Subsystem 100 provides electrical signals, inputs and outputs (I/Os), and power 164 to optical engine 130 via the electrical interposer 110. The electrical interposer 110 is generally used as an intermediate component to pitch match electrical connections 164 between the optical engine 130, with a dense pitch, to the power delivery subsystem 100. The optical engine 130 includes integrated circuits (not shown) and optoelectronic devices (not shown) that can transmit or receive optical 166 and electrical signals 164.

The optical signals 166, in multiple wavelengths 170, are sent from optical engine 130 to an optical element 120 to wavelength multiplex them into a single optical fiber core 140. The multi-wavelength optical signals 170, 166, 168 enable >1 Tb/s of connectivity. The highest power density is concentrated within the optical engine 130 so a cooling subsystem 150 is provided for the module to operate within a desired temperature range. The cooling subsystem 150 is in direct contact with the bare semiconductor die of the optical engine 130. The heat exchange 162 between the optical engine 130 and the cooling subsystem 150 is through physical contact of the said components. The physical contact may be improved by using an interlayer such as thermal interface material (not shown). The cooling subsystem 150 efficiency helps the optical element 120 to not degrade its performance during normal operation.

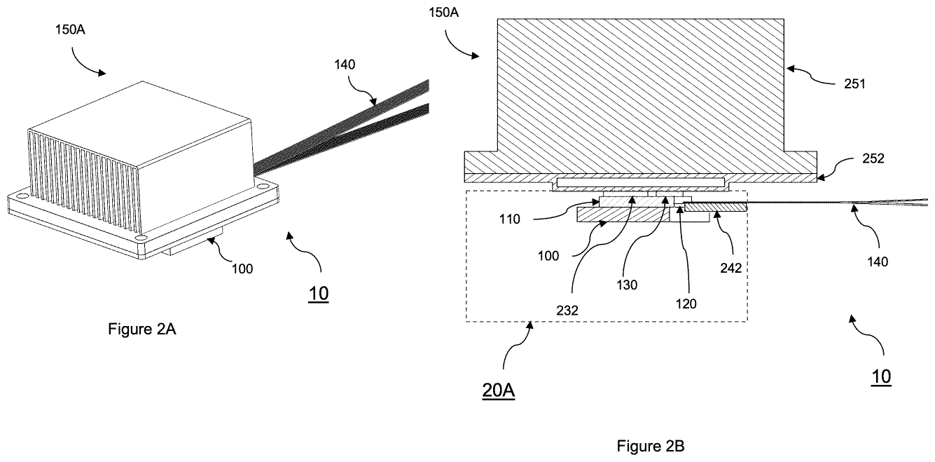

In an exemplary embodiment, FIG. 2A, the air-cooling subsystem 150A is directly attached to the optical engine 130 (see FIG. 2B) such that the heat 162 generated during the distribution of electrical and optical power is effectively spread using an evaporative vapor chamber 252 and dissipated through a finned heat sink 251. The optical fiber 140 used as a medium to receive and transmit information at high bandwidth is shown.

In FIG. 2B, the optical element 120 is compactly integrated onto the package with electrical interposer 110, and optical engine 130, this package 20A is compact with a resulting thickness in general between 0.1 mm and 5 mm. This is advantageous for the package 20 to fit within an standard 1-rack unit while leaving sufficient real estate for a cooling subsystem 150. FIG. 2B also shows an intermediary fiber array holder 242 used to guide the cores within fiber optics cable 140 into the optical path to direct the optical signals 168 into and out of the optical element 120 coupled to the photonic engine 130. The cooling subsystem 150 includes an evaporative chamber 252 for heat spreading into the cooling subsystem 150.

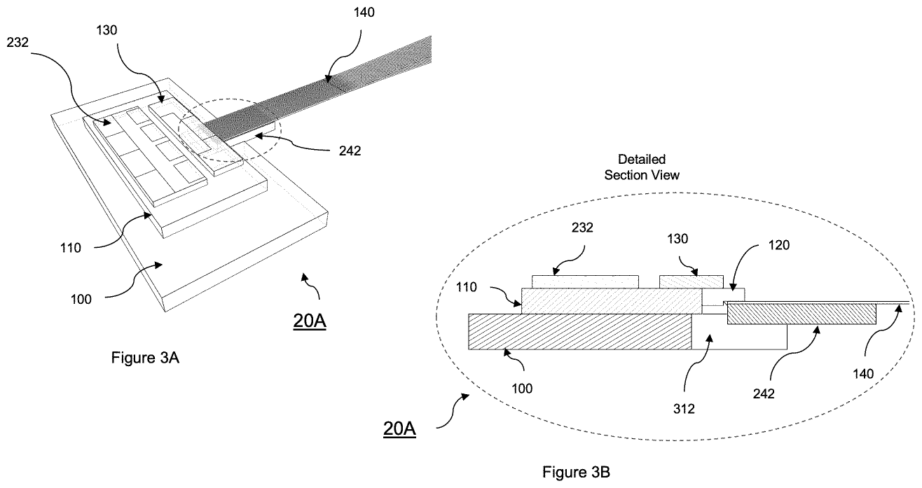

FIG. 3A shows a detailed view of the optical engine 130 packaged with the electrical interposer 110 and electrical signal and power delivery subsystem 100. The interposer 110 may have more than one type of integrated circuit (IC) on it. In this embodiment, it includes a secondary IC 232. The secondary IC 232 is an application specific IC used for computations or traffic routing. It will be apparent to someone skilled in the art that multiple optical engines 130, with their respective optical element 120, optical fiber array holder 242 and fibers 140, and application specific ICs 232 may be combined onto a single interposer 110. With this packaging approach, the electrical power delivery to the optical engine 170 is optimized by using the available electrical interposer 110 perimeter to go to the center of the optical engine 130. It also allows the electrical signal and power delivery subsystem 100 to be integrated with mezzanine style high bandwidth detachable connectors (not shown). In this embodiment, the discretization of the cooling subsystem 150 and electro-optical power and signal delivery system 100 ensures that the stack-up can be effectively integrated and assembled, while maintaining thermomechanical stability and minimizing loss due to misalignments during operation.

FIG. 3B depicts a detailed cross section of the apparatus 20A showing a cutout 312 in the electrical interposer 110 used to fit in the optical element 120 in between the interposer 110 and the power delivery subsystem 100. The cutout allows the optical element 120 to be directly physically coupled to the optical engine 130 which allows for the mechanical tolerance loop between the optical engine 130 and the optical element 120 to be minimized. The cutout reduces the available surface area available between the electrical interposer and the photonic engine 130. Thus, the power integrity of the chip benefits from careful optimization to use the limited perimeter surrounding the photonic engine 130.

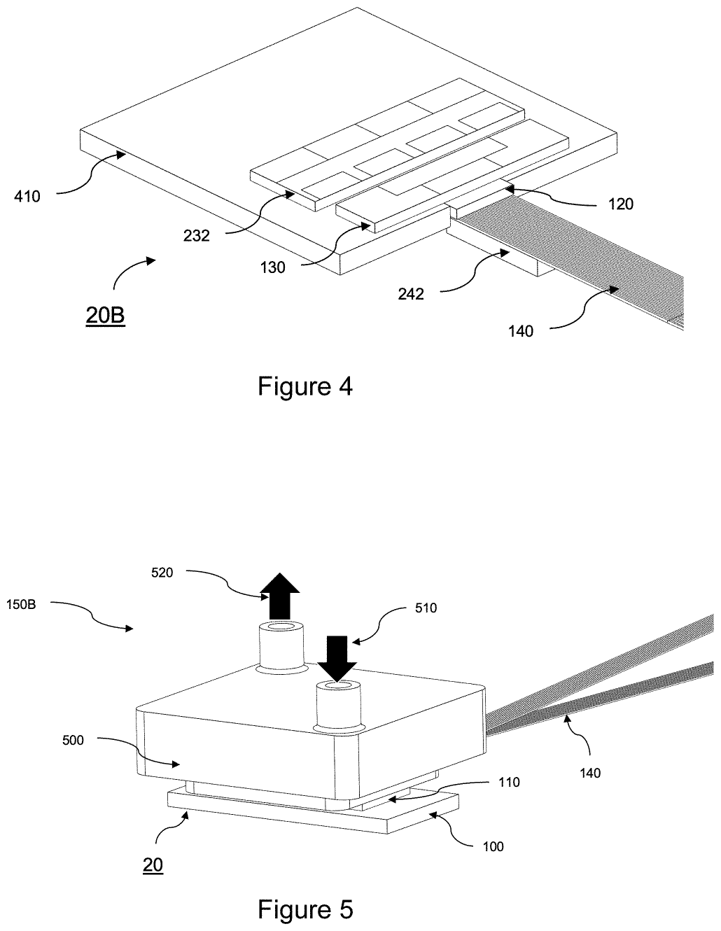

FIG. 4 depicts another embodiment 20B in which the electrical signal and power delivery subsystem and the interposer exist on a single layer with passive and active electrical components (not shown) integrated onto an active interposer 410. This approach optimizes the electrical and optical power and signal delivery to and from the individual components on the packaged substrate.

In another embodiment, FIG. 5 depicts a direct-to-chip liquid cooling subsystem 500 including but not limited to cold plates with mini-channels (not shown), micro-channels (not shown) and immersion cooling (not shown) for heat removal from the system. In this embodiment cold liquid 510 enters the cooling subsystem 500, extracts the heat from the system and warm liquid 510 exits the cooling subsystem 500. The use of a liquid cooling approach ensures that the power usage effectiveness at a system-level is optimized and adapted to commonly available data-center infrastructures.

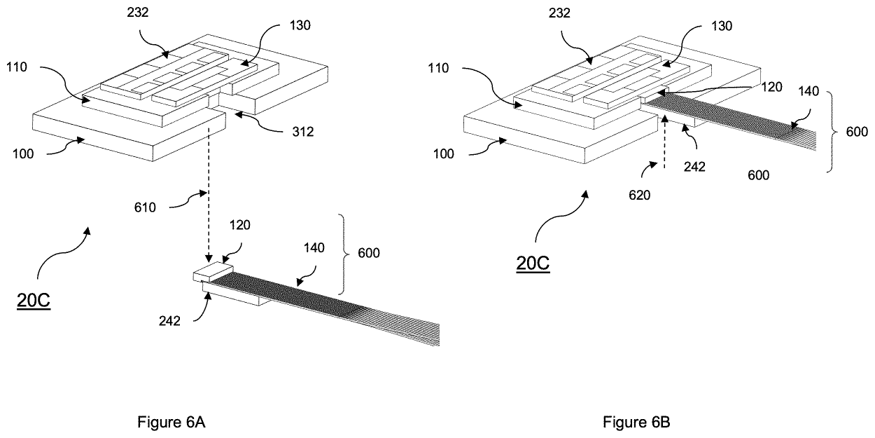

FIGS. 6A and 6B show another embodiment 20C in which the optical element 120 including the fiber 140 and fiber array holder 242, henceforth called optical sub-system 600 is detachable and re-attachable from the optical engine 130. This enables the optical engine to be assembled with all the known packaging industry methods, including solder reflow temperatures exceeding 260° C., and have the optical subsystem 600 attached to the module as the last assembly step.

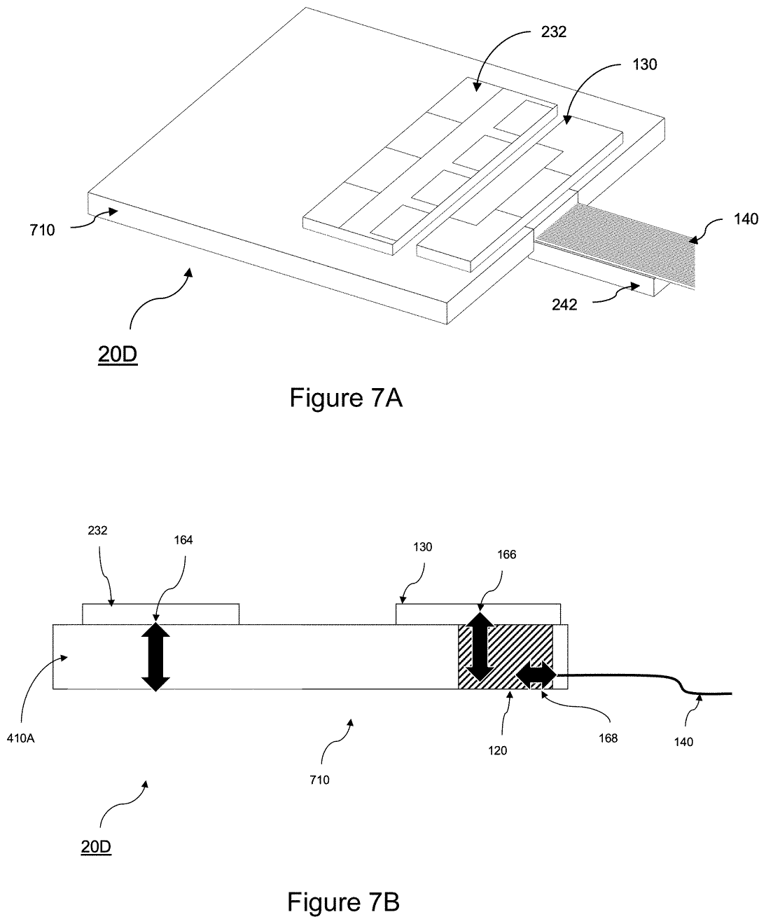

In another embodiment, FIG. 7A depicts an apparatus 20D with an interposer 710 that is capable of embedding optical and electrical elements of the system. The cutaway depiction of the embodiment shown in FIG. 7B shows both the optical element 120 and an active interposer 410A embedded in a common substrate. The substrate uses materials that are compatible with optical signal delivery 166, 168 that are capable of managing multiple wavelengths generated in the optical engine 130 and electrical power and signal delivery 164. An example of this interposer is a Si-based substrate with waveguides for optical signal delivery 166, 168, and passive and active electronic devices (not shown) for electrical power and signal delivery 164. This embodiment enables a compact system where the number of alignment steps are reduced because the components of the system are combined.

While the exemplary preferred embodiments of the present invention are described herein with particularity, those skilled in the art will appreciate various changes, additions, and applications other than those specifically mentioned, which are within the spirit of this invention.

What is claimed is:

1. Apparatus comprising:
an electrical signal and electrical power delivery subsystem;
an optical engine;
an electrical interposer between the electrical signal and electrical power delivery subsystem and the optical engine; and
an optical element configured to exchange optical signals with the optical engine and to exchange optical signals and optical power with an optical interface;
wherein electrical signals and electrical power delivery from the electrical interposer to the optical engine and optical signal delivery from the optical element to the optical engine are provided through a common plane on the optical engine.

2. The apparatus of claim 1, wherein optical signal delivery from the optical interface to the optical element travels perpendicular to the common plane.

3. The apparatus of claim 1, wherein optical signal delivery from the optical interface to the optical element travels parallel to the common plane.

4. The apparatus of claim 1, wherein the optical element adjoins the electrical interposer.

5. The apparatus of claim 1, wherein the optical engine has a cooling subsystem adjoining it.

6. The apparatus of claim 5 wherein the cooling subsystem adjoins the optical engine on a surface that is parallel to the common plane and spaced apart from the common plane.

7. The apparatus of claim 5, where in the cooling subsystem is in direct contact with a bare semiconductor die on the optical engine.

8. The apparatus of claim 5, wherein the cooling subsystem includes air-assisted heat transfer.

9. The apparatus of claim 5, wherein the cooling subsystem includes liquid-assisted heat transfer.

10. The apparatus of claim 5, wherein the cooling subsystem includes a combination of cooling mechanisms.

11. The apparatus of claim 1, further comprising a cutout in the electrical interposer and wherein optical signals are delivered to the optical engine through the cutout.

12. The apparatus of claim 1, wherein the optical element is a detachable component.

13. The apparatus of claim 1, wherein optical signals and electrical signals and electrical power are delivered to the optical engine via a common substrate.

14. The apparatus of claim 13 wherein the optical element is packaged in the common substrate.

15. Apparatus comprising:
an electrical signal and electrical power delivery subsystem;
an optical engine;
an electrical interposer between the electrical signal and electrical power delivery subsystem and the optical engine;
an optical element configured to exchange optical signals with the optical engine and to exchange optical signals and optical power with an optical interface; and
a cooling subsystem adjoining the optical engine;
wherein electrical signals and electrical power delivery from the electrical interposer to the optical engine and optical signal delivery from the optical element to the optical engine are provided through a common plane on the optical engine; and
wherein the cooling subsystem adjoins the optical engine on a surface that is parallel to the common plane and spaced apart from the common plane.

16. The apparatus of claim 15 wherein the cooling subsystem includes air-assisted heat transfer.

17. The apparatus of claim 15 wherein the cooling subsystem includes liquid-assisted heat transfer.

18. Apparatus comprising:
an electrical signal and electrical power delivery subsystem;
an optical engine;
an electrical interposer between the electrical signal and electrical power delivery subsystem and the optical engine; and
an optical element configured to exchange optical signals with the optical engine and to exchange optical signals and optical power with an optical interface;
wherein electrical signals and electrical power delivery from the electrical interposer to the optical engine and optical signal delivery from the optical element to the optical engine are provided through a common plane on the optical engine; and
wherein the optical engine adjoins the electrical interposer.

19. The apparatus of claim 18 wherein the electrical interposer forms a cutout and optical signals are delivered to the optical engine through the cutout.

20. The apparatus of claim 19 wherein a thickness of the optical engine, the electrical interposer, and the optical element combined is under 5 mm.
